(19) United States
(12) Patent Application Publication
(10) Pub. No.: US 2026/0330092 A1
(43) Pub. Date: Oct. 22, 2026

(54) COMPUTER AND DESIGN SUPPORT METHOD FOR DESIGN INFORMATION

(71) Applicant: Hitachi, Ltd., Tokyo (JP)

(72) Inventors: Keigo NAKAMURA, Tokyo (JP); Kenta NAITO, Tokyo (JP); Shin YABUUCHI, Tokyo (JP)

(21) Appl. No.: 19/536,324

(22) Filed: Feb. 11, 2026

(30) Foreign Application Priority Data
Apr. 22, 2025 (JP) 2025-070459

(51) Int. Cl. G06F 30/20; G06F 16/3329

(52) U.S. Cl. CPC G06F 30/20; G06F 16/33295

(57) ABSTRACT

A computer that supports design for design information generate second hierarchized design information by hierarchizing target design information; search for the first hierarchized design information including the same element as the element included in the second hierarchized design information with reference to the first hierarchized design information and the second hierarchized design information in the same level; search for the case data in which a combination of the element and the design purpose included in the second hierarchized design information matches a combination of the element and the change purpose of the element, from pieces of the case data associated with the searched first hierarchized design information; and generate a design proposal in which the target design information is modified according to the design purpose by inputting a prompt including the searched first hierarchized design information and the searched case data to a language model.

### CLAIM OF PRIORITY

The present application claims priority from Japanese patent application No. 2025-070459 filed on Apr. 22, 2025, the content of which is hereby incorporated by reference into this application.

### BACKGROUND

The present invention relates to a technology for efficiently designing an apparatus or a system according to a purpose, and particularly to a design support method and a design support apparatus for automatically generating a design proposal by utilizing past design information.

When designing a new apparatus or system, reducing design cost is an important issue. When performing design improvement, it is common in many cases to generate a design proposal suitable for a development purpose with reference to existing design information and past cases.

In the design process, a process of searching for past cases, modifying the original design based on the search results, and reviewing a new design proposal is particularly important. However, such a process requires a lot of time and effort, and there is no guarantee that the searched past cases are suitable for new apparatuses and systems, and as a result, rework to review of the design proposal may occur. Therefore, it is extremely important to reduce effort in generating a design proposal and minimize rework in order to reduce the entire design cost.

As a conventional example of a software design support technology, JP 2007-086929 A discloses an apparatus and a method for supporting efficient reusable design by associating a characteristic of a product series with a reusable software component. In addition, as a conventional example related to a part design support technology, WO 2020/188869 A discloses a method and an apparatus for generating a verification procedure based on a design guideline.

However, such related arts present several challenges. The technologies disclosed in JP 2007-086929 A and WO 2020/188869 A are established by joining elements having no correlation or relationship with each other, such as independent software components and design verification procedures. On the other hand, in a design having a complex structure such as an apparatus or a system, a design considering mutual relationships and connections between elements is required. In such a case, it is necessary to dynamically rewrite a basic design based on past cases, but the related arts have a problem in that it is not possible to support automatic generation and adjustment of a design proposal in consideration of a complex system configuration.

Therefore, in designing an apparatus and a system, there is a demand for development of a technology for efficiently utilizing past design cases and automatically generating a design proposal in consideration of a complex relationship between elements.

### SUMMARY

The invention described in JP 2007-086929 A supports a search function using a level structure, but does not support processing intended for rewriting a basic design. Therefore, such invention is limited to simply searching for and extracting past corresponding cases, and then applying the cases, and pre-processing necessary for rewriting the basic design is not sufficiently considered. As a result, there is a problem in that it is difficult to appropriately modify the basic design and efficiently and accurately generate and output a new design proposal.

In addition, the technology disclosed in WO 2020/188869 A has a function of defining a determination rule based on a design guideline and generating a verification procedure by combining common functions corresponding to the determination rule. However, such a technology is also limited to generating the verification procedure based on the existing determination rule or common functions, and does not consider accurately rewriting the basic design while utilizing past cases according to a design purpose or a situation of the basic design in a complex task such as apparatus or system design. Therefore, it is still difficult to implement efficient and accurate generation of a design proposal in a complex design task.

The present invention provides a technology for efficiently extracting a past case in order to modify a basic design by using a trained model.

The representative aspects of this invention are as follows. That is, there is provided a computer that supports design for design information including definitions of elements included in an object that is a design target, the computer comprising: a processor; a storage device connected to the processor; and a network interface connected to the processor, wherein the storage device is configured to store first hierarchized design information obtained by classifying the elements included in past design information of the object based on a hierarchization rule for the elements and grouping the elements by the same level, and case data in which the element included in the past design information is associated with a change purpose and a change content of the element, and the processor is configured to: receive target design information and a design purpose; generate second hierarchized design information by hierarchizing the target design information; search for the first hierarchized design information including the same element as the element included in the second hierarchized design information with reference to the first hierarchized design information and the second hierarchized design information in the same level; search for the case data in which a combination of the element and the design purpose included in the second hierarchized design information matches a combination of the element and the change purpose of the element, from pieces of the case data associated with the searched first hierarchized design information; and generate a design proposal in which the target design information is modified according to the design purpose by inputting a prompt including the searched first hierarchized design information and the searched case data to a language model.

According to the present invention, it is possible to extract a past case suitable for a design purpose and an element. Problems, configurations, and effects other than those described above will be clarified by the following description of embodiments.

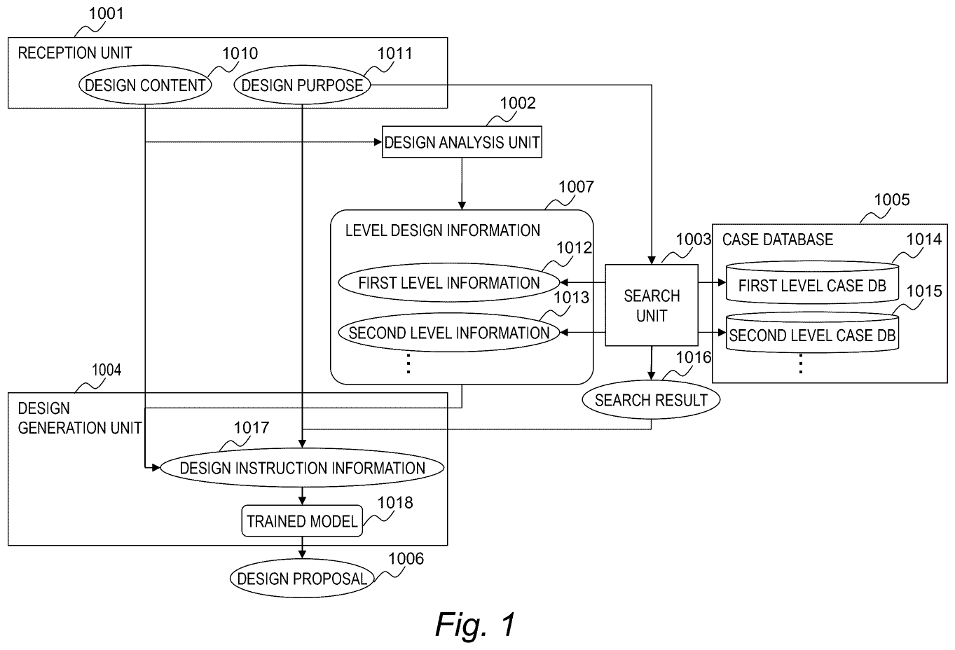

FIG. 1 is a diagram illustrating a basic configuration of a design support apparatus according to a first embodiment.

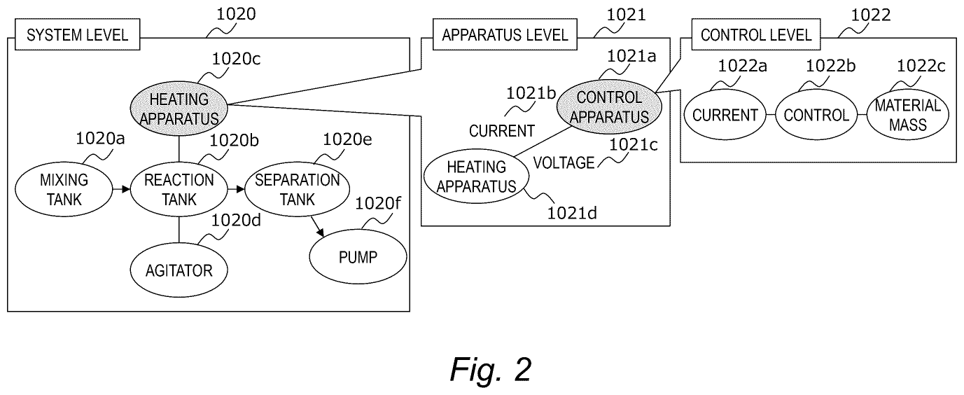

FIG. 2 is a diagram illustrating an example of level information included in the level design information and the case database.

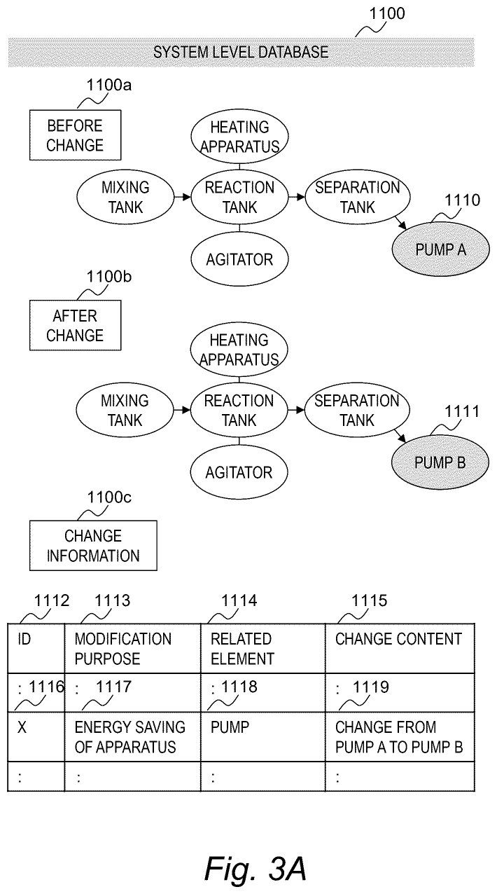

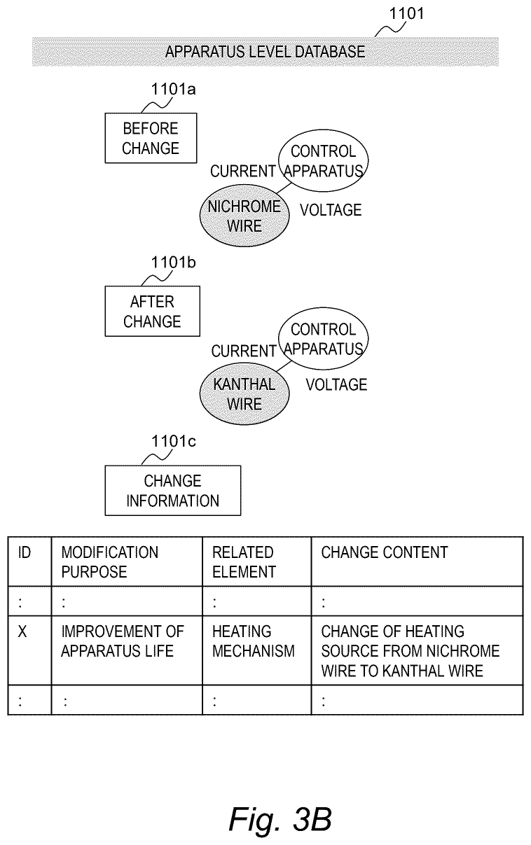

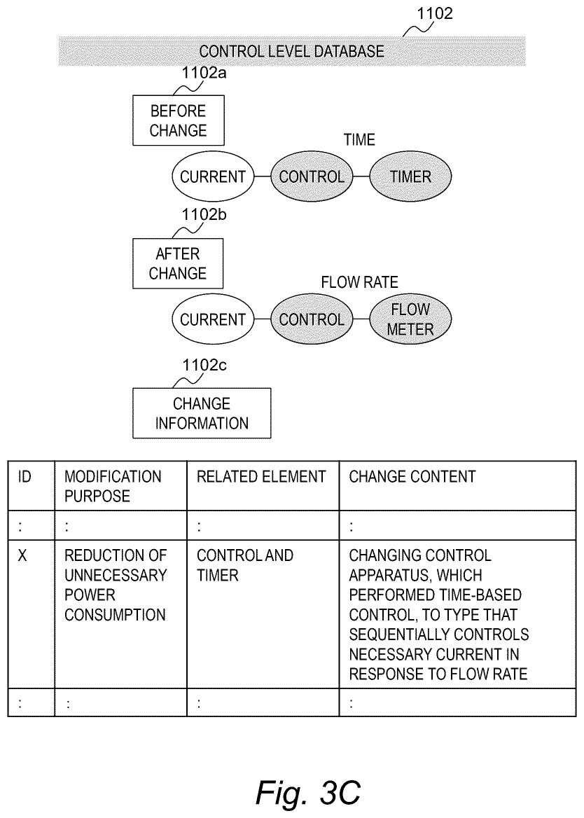

FIGS. 3A, 3B, and 3C are diagrams illustrating an outline of information included in the case database.

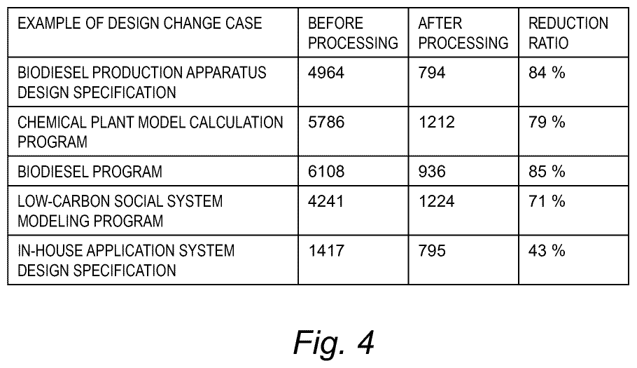

FIG. 4 is a diagram illustrating a specific example illustrating an amount of information that can be reduced by generating the change content from the pre-change design information and the post-change design information.

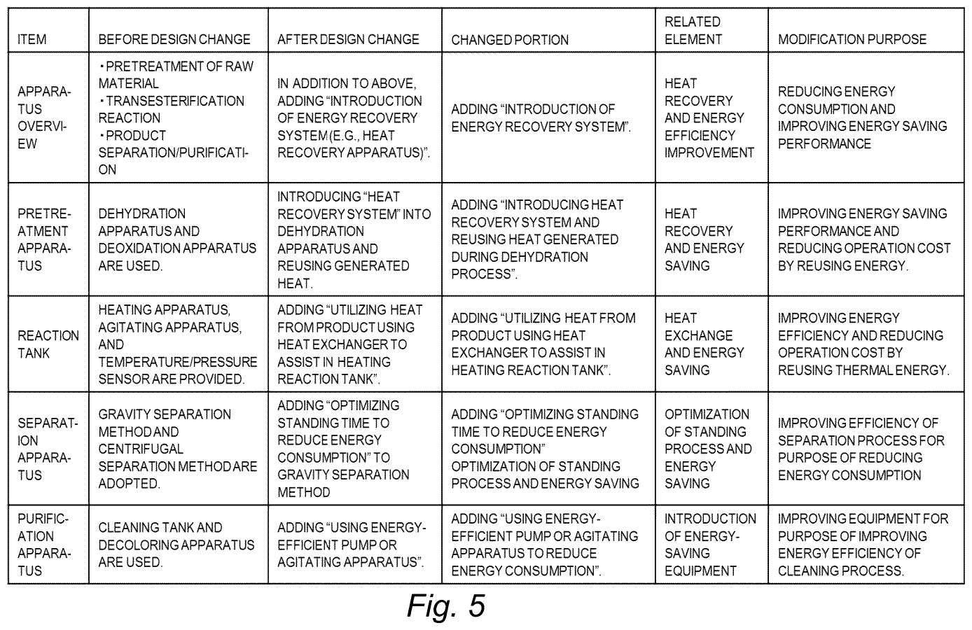

FIG. 5 is a diagram illustrating a specific example of the generation of the change content related to a biodiesel production apparatus design specification.

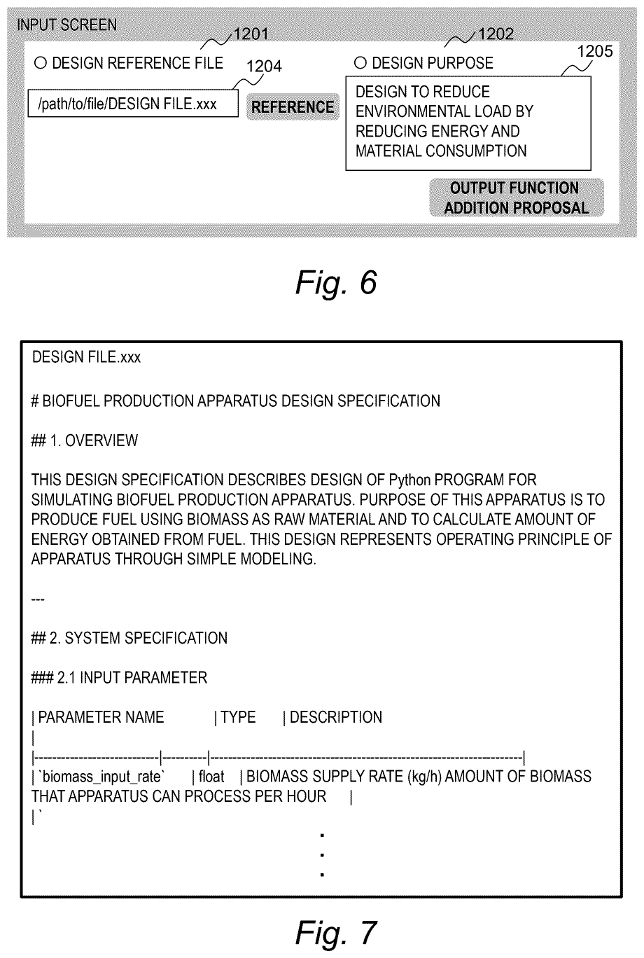

FIG. 6 is a view illustrating an example of an input user interface for providing input information to the reception unit.

FIG. 7 is a view illustrating a part of a design file designated through the file designation interface.

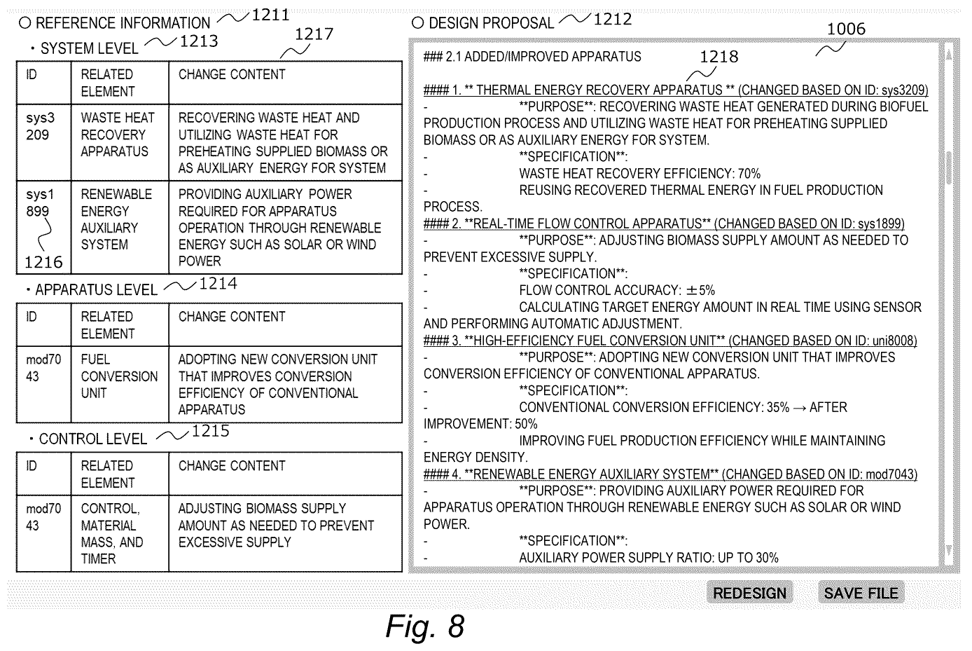

FIG. 8 is a view illustrating a specific example of a design proposal output screen.

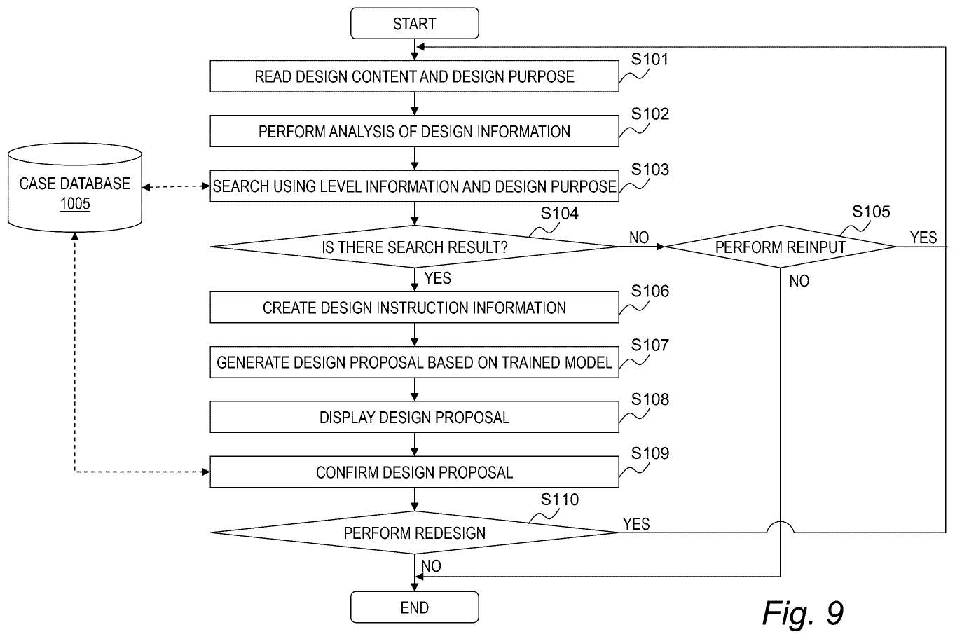

FIG. 9 is a diagram illustrating a flowchart of a design generation process according to the first embodiment.

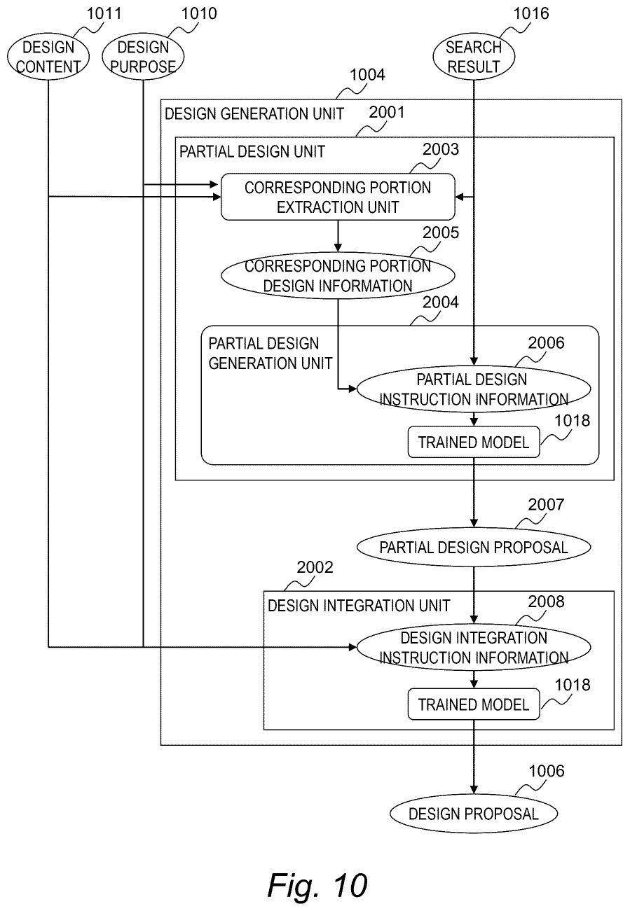

FIG. 10 is a diagram illustrating a part of a configuration of a design support apparatus to which a partial design function in the second embodiment is added.

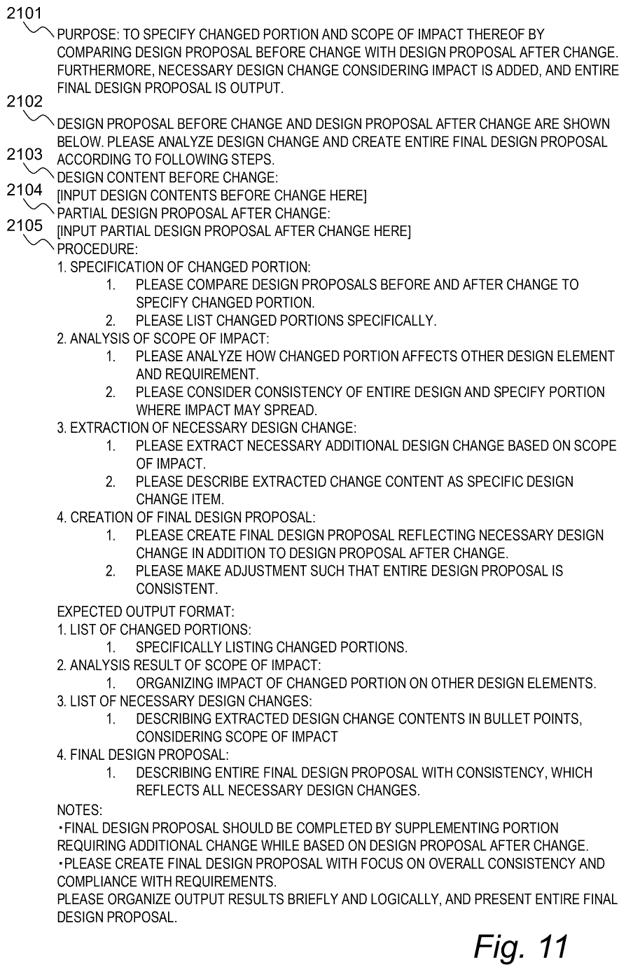

FIG. 11 is a view illustrating an example of a design integration instruction information template.

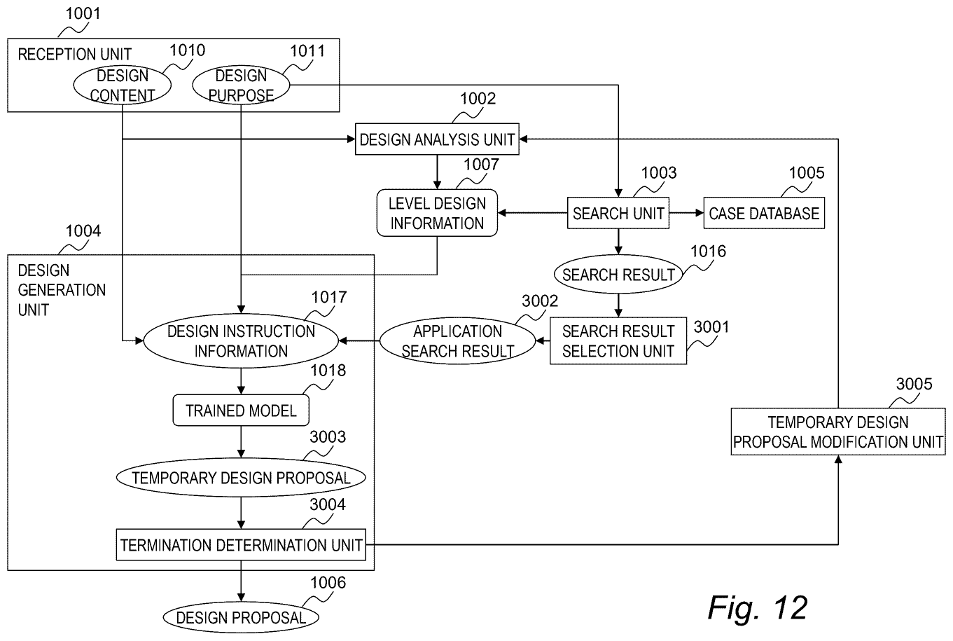

FIG. 12 is a diagram illustrating a configuration of a design support apparatus to which an iteration function is added.

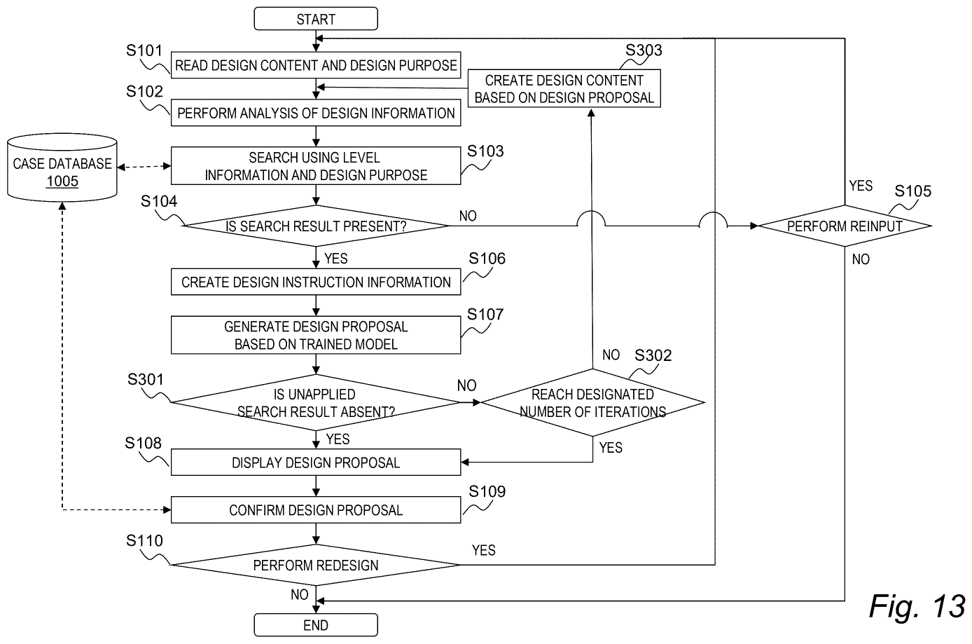

FIG. 13 is a diagram illustrating a flowchart illustrating an iterative design generation process of the design support apparatus with the iteration function.

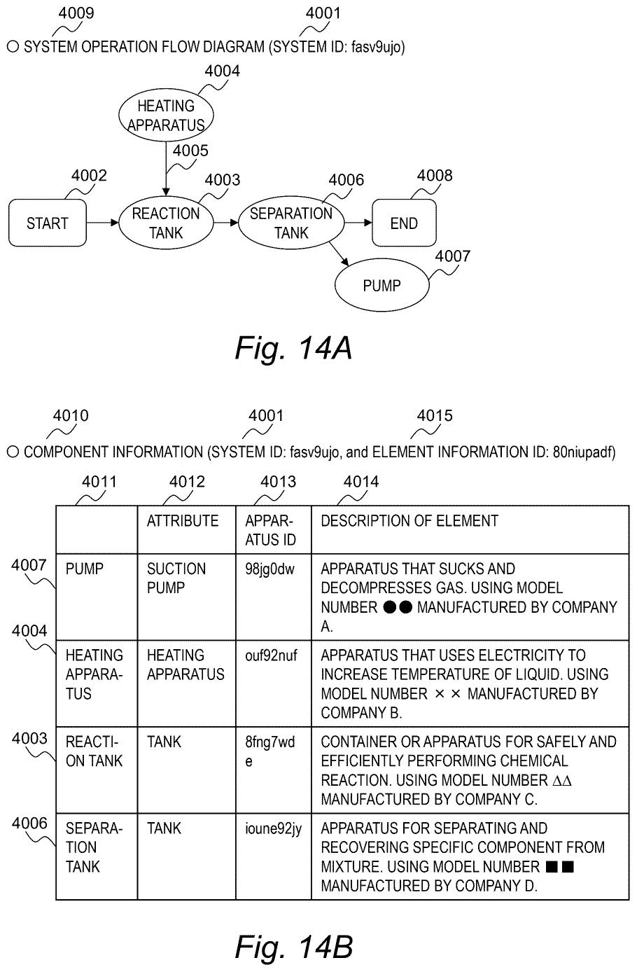

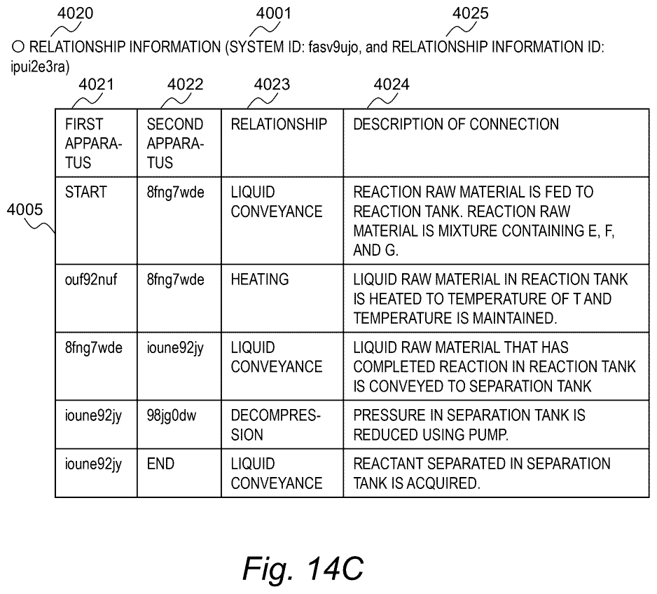

FIGS. 14A, 14B, and 14C are diagrams illustrating examples of system level information including connection information.

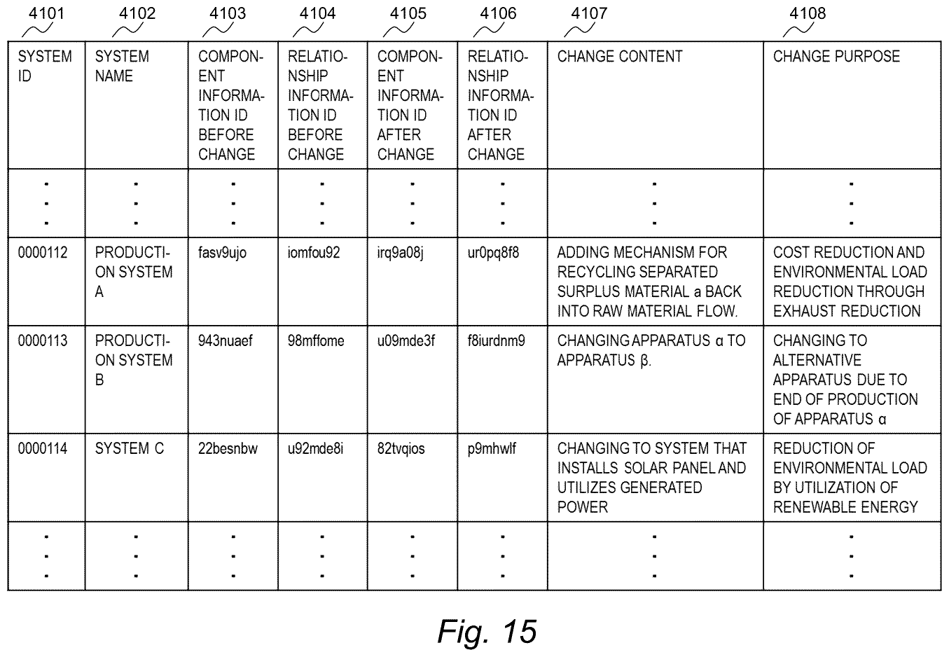

FIG. 15 is a diagram illustrating an example of a connection-information-containing system level database.

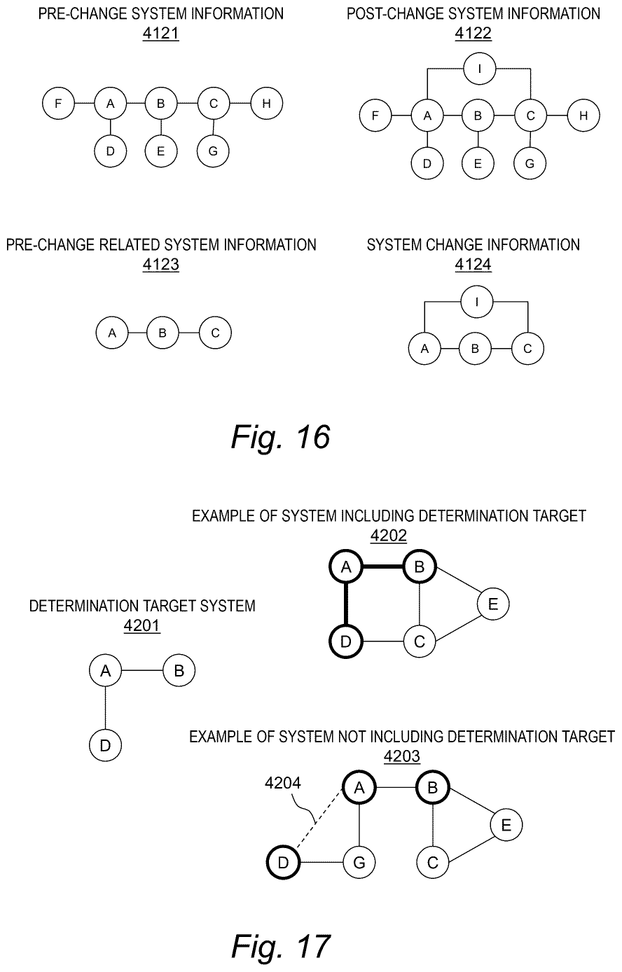

FIG. 16 is a diagram illustrating an outline of a process of extracting difference information by using elements and a connection of design change information.

FIG. 17 is a diagram illustrating a specific example of the partial isomorphism determination.

### DETAILED DESCRIPTION OF THE PREFERRED EMBODIMENTS

Hereinafter, embodiments of the present invention will be described with reference to the drawings.

### First Embodiment

FIG. 1 is a diagram illustrating a basic configuration of a design support apparatus 10 according to a first embodiment.

The design support apparatus 10 is implemented by a computer including a processor, a memory, an auxiliary storage device, and a communication interface, and may include an input user interface and an output user interface.

The design support apparatus 10 includes a reception unit 1001, a design analysis unit 1002, a search unit 1003, a design generation unit 1004, and a case database 1005, and generates a design proposal 1006 using the above units. The reception unit 1001, the design analysis unit 1002, the search unit 1003, and the design generation unit 1004 are implemented by the processor (not illustrated) executing a program stored in the memory.

The reception unit 1001 receives a design content 1010 and a design purpose 1011.

The design content 1010 is basic design information defining components of an apparatus or a system (object) and relevance between the components, and corresponds to a design document, a design program, a specification, or the like. The design purpose 1011 is information indicating goals and requirements to be achieved in a design change or new design.

The design analysis unit 1002 analyzes the design content 1010 received by the reception unit 1001 and generates level design information 1007.

The level design information 1007 is information in which elements included in the design content 1010 are classified into a plurality of levels and grouped by each level. In the present embodiment, the level design information 1007 includes first level information 1012 and second level information 1013. The level design information 1007 includes information regarding each element, a connection between the elements, an effect achieved by a system operation, and the like, and may be held as structured data (for example, a component list, a design parameter, and table information regarding a system configuration) or unstructured data (for example, a design drawing, CAD data, a specification, and a simulation result).

In addition, it is also possible to adopt a method of integrating and managing such structured data and unstructured data. For example, in production system design, the first level information 1012 corresponds to a system level, and the second level information 1013 corresponds to an apparatus level. A lower level holds detailed information regarding elements included in a higher level.

The search unit 1003 searches for a suitable past design case from the case database 1005 based on the level design information 1007 obtained from the design analysis unit 1002 and the design purpose 1011 received by the reception unit 1001, and extracts a search result 1016.

The case database 1005 corresponds to a level structure of the level design information 1007, and includes a first level case database (DB) 1014 corresponding to the first level information 1012 and a second level case DB 1015 corresponding to the second level information 1013.

The search result 1016 is not limited to information of a single level, and may include a plurality of pieces of information over a plurality of levels. As a result, it is possible to extract a past design case for achieving various purposes in the plurality of levels.

The design generation unit 1004 generates design instruction information 1017 based on the design content 1010 and the design purpose 1011 received by the reception unit 1001 and the search result 1016 extracted by the search unit 1003.

The design instruction information 1017 is information (prompt) that includes the design purpose 1011 and describes a content of a task to be executed by a trained model 1018. The design generation unit 1004 generates the design proposal 1006 by inputting the design instruction information 1017 to the trained model 1018. Since the design purpose 1011 is specifically described in the design instruction information 1017, the trained model 1018 can clearly determine how the design content 1010 is to be modified. As a result, a more accurate and efficient design proposal 1006 can be generated.

The trained model 1018 is, for example, a large language model, and executes a task according to a prompt.

As described above, in the present embodiment, it is possible to implement efficiency improvement and quality improvement of design work through hierarchical analysis for the design content, extraction of an appropriate past case, and design proposal generation utilizing the trained model.

FIG. 2 is a diagram illustrating an example of level information included in the level design information 1007 and the case database 1005. FIG. 2 illustrates an example in which a production system for a certain chemical material using a chemical reaction is assumed, and the production system is expressed by being divided into three levels of a system level 1020, an apparatus level 1021, and a control level 1022.

The system level 1020 is a level representing the entire production system including a plurality of apparatuses connected to each other. In an example of the system level 1020 in FIG. 2, materials mixed in a mixing tank 1020a are sent to a reaction tank 1020b and agitated by an agitator 1020d while being heated by a heating apparatus 1020c. FIG. 2 illustrates a subsequent flow of the entire system in which a mixture of the materials whose reaction has been completed is introduced into a separation tank 1020e, and the mixture of the materials is separated while being decompressed by a pump 1020f.

The apparatus level 1021 is a level representing detailed apparatus configuration information regarding each apparatus which is a component in the system level 1020, and is implemented by a connection between functions of the respective apparatuses. As an example of the apparatus level 1021 in FIG. 2, an internal configuration of a heating apparatus 1021d is illustrated. The heating apparatus 1021d is an apparatus having a mechanism for performing heating when a control apparatus 1021a inputs a current 1021b and a voltage 1021c to the heating apparatus 1021d.

The control level 1022 is a level representing detailed configuration information regarding each function which is a component in the apparatus level 1021, and represents a control mechanism implemented by a connection between a plurality of functions. In an example of the control level 1022 in FIG. 2, a control method executed inside the control apparatus 1021a is illustrated. The control apparatus 1021a is a mechanism that performs control 1022b based on an input material mass 1022c and outputs a current 1022a as a result.

In this manner, by classifying design information into a plurality of levels such as the system level 1020, the apparatus level 1021, and the control level 1022, it is possible to structure the design information and efficiently and accurately extract information suitable for the design purpose from past cases. As a result, appropriate information for achieving a purpose of a design task can be easily utilized, and efficiency improvement and quality improvement of the entire design process can be expected.

FIGS. 3A, 3B, and 3C are diagrams illustrating an outline of information included in the case database 1005. The case database 1005 having a structure similar to the level structure illustrated in FIG. 2 is illustrated.

The case database 1005 includes a system level database 1100, an apparatus level database 1101, and a control level database 1102, and stores the design information corresponding to each level. The corresponding design information is information obtained by hierarchizing the design content 1010, includes information regarding each element, a connection between the elements, an effect achieved by a system operation, and the like, and may be held as structured data (for example, a component list, a design parameter, and table information regarding a system configuration) or unstructured data (for example, a design drawing, CAD data, a specification, and a simulation result). In addition, it is also possible to adopt a method of integrating and managing such structured data and unstructured data.

The system level database 1100 stores pre-change design information 1100a, post-change design information 1100b, and change information 1100c of the system. Similarly, the apparatus level database 1101 stores pre-change design information 1101a, post-change design information 1101b, and change information 1101c of the apparatus, and the control level database 1102 stores pre-change design information 1102a, post-change design information 1102b, and change information 1102c of the control.

In this manner, the case database 1005 stores the design information before and after the change and the change information thereof for each level. The change information is information regarding design modification, and includes a case database ID 1112, a modification purpose 1113, a related element 1114, and a change content 1115. In the change information, design information hierarchized based on the same system or apparatus is managed by the same case database ID 1112.

The pre-change design information 1100a, the pre-change design information 1101a, the pre-change design information 1102a, the post-change design information 1100b, the post-change design information 1101b, and the post-change design information 1102b may be managed by an ID. For example, the change information 1100c, the change information 1101c, and the change information 1102c may store a pre-change ID and a post-change ID.

The design support apparatus 10 collates the design information before the design change of the past case with the level design information 1007 to extract information applicable to a change of the design content 1010.

In such a search process, various search methods are conceivable. For example, there is a method of including, in the search result 1016, the design information before the design change of the past case as corresponding information in a case where all elements (an aggregate having one operation function such as an apparatus, a function, and a control) in each level included in the design information before the design change of the past case are included in the level design information 1007. In addition, a method of performing search by converting pre-design change information of the past case and the level design information 1007 into multidimensional vectors by using a pre-trained embedding function, and evaluating similarity of each vector is also effective.

Furthermore, in a case where the information in the case database 1005 is held in a format different from a storage format of the level design information 1007, a multimodal data processing technology can be utilized as a method of integrally processing pieces of data in different formats. In such a technology, data is converted into a multidimensional vector using a trained embedding function, and meanings of respective pieces of information are extracted to interconvert semantic spaces. In addition, by analyzing a co-occurrence relationship, it is also possible to search for matching information among data of different formats.

In an example of the system level database 1100 in FIG. 3A, a pump A 1110 used in the pre-change design information 1100a is changed to a pump B 1111 in the post-change design information 1100b. In the change information 1100c corresponding to the change, as a specific example, the case database ID 1112 is “X1116”, the modification purpose 1113 is “energy saving of apparatus”, the related element 1114 is “pump 1118”, and the change content 1115 is “change 1119 from pump A to pump B”.

By including the modification purpose 1113 in the database, a corresponding search based on the design purpose 1011 becomes possible, and by using the related element 1114, a search by collation with the level design information 1007 becomes possible. In addition, by including the change content 1115, it is possible to accurately grasp the change content of the design and to more accurately modify the design content 1010 than a case of directly inputting the past case to a generative AI.

The modification purpose 1113 and the change content 1115 are generated by associating the pre-change design information 1100a and the post-change design information 1100b. Examples of a generation method therefor include a method in which a user directly uses information recorded at the time of design change, and a method in which the change content is automatically generated using the generative AI.

As a result, it is possible to generate the design proposal in which the design content 1010 is accurately and efficiently modified by utilizing the case database 1005. Efficiency improvement and quality improvement of design work can be implemented through integrated utilization of hierarchical design information and past cases.

FIG. 4 is a diagram illustrating a specific example illustrating an amount of information that can be reduced by generating the change content 1115 from the pre-change design information 1100a and the post-change design information 1100b.

Since the change content 1115 is a portion that stores information corresponding to a difference between the pre-change design information 1100a and the post-change design information 1100b, the amount of information to be stored is greatly reduced as compared with a case of directly holding the design information before and after the change. As a result, it is possible to achieve improvement in processing efficiency and clarification of an important point in a design change.

In the example illustrated in FIG. 4, an information amount reduction effect in the generation of the change content 1115 for various design documents and programs used for a design change is illustrated. Based on the example, a reduction rate of the amount of information reaches from 43% to 85%, which indicates that the amount of information can be greatly reduced in the design process, and it becomes possible to clearly indicate an important point in a design change.

FIG. 5 is a diagram illustrating a specific example of the generation of the change content 1115 related to a biodiesel production apparatus design specification.

In this case, when the pre-change design information 1100a and the post-change design information 1100b are directly used, both are redundant design documents, and thus, the number of characters becomes enormous, which results in inefficient input processing to the trained model 1018 and inefficient determination of a design change. However, as illustrated in FIG. 5, by extracting and using only difference information as the change content 1115, it is possible to accurately point out a point to be noted in the design change. As a result, the generative AI (trained model 1018) can appropriately and efficiently change the design content 1010.

Specifically, the change content 1115 clarifies the related element in the design change and the modification purpose, and precisely specifies a changed portion, thereby providing a guideline for reflecting the information after the design change without excess or deficiency. By utilizing such difference information, it is possible to reduce a processing load of the generative AI and improve accuracy in the design change as compared with a case of using the conventional redundant design information as it is.

As described above, generating the change content 1115 and utilizing the change content 1115 as the difference information is an effective method for improving efficiency in information management in the design process and improving quality of design proposal generation. Furthermore, such a method provides an environment in which the trained model 1018 can quickly and appropriately understand and reflect a content of the design change, and contributes to improvement of efficiency of the entire design work and shortening of lead time.

FIG. 6 is a view illustrating an example of an input user interface 1200 for providing input information to the reception unit 1001.

In the input user interface 1200, the design content 1010 and the design purpose 1011 can be input. The design content 1010 can be input by designating a file using a design reference file 1201, and the design purpose 1011 is input by inputting characters in a design purpose input form 1202.

Examples of a method of inputting the design content 1010 include a plurality of methods such as a method of uploading a file such as a design document or a design drawing using a file designation interface 1204, a method of directly inputting character information, and a method of giving a design instruction using the generative AI and generating a basic design based on the design instruction.

Meanwhile, the design purpose 1011 is information instructing what modification is to be made for the design content 1010 input to the reception unit 1001, and can be input with characters such as a sentence 1205 through the design purpose input form 1202, or can be input in a format selected from a plurality of options.

FIG. 7 is a view illustrating a part of a design file designated through the file designation interface 1204.

As illustrated in the example, the design content 1010 can be input in any format such as a program code or a design drawing describing a connection between apparatuses, in addition to language information such as a design document. As a result, design data in various formats can be received by the reception unit 1001 and used for processing in the design support apparatus 10.

FIG. 8 is a view illustrating a specific example of a design proposal output screen 1210.

The design proposal output screen 1210 is a screen for displaying the design proposal 1006 generated by the design generation unit 1004, and provides information for a designer to confirm a generation result and to perform review and correction as necessary. The design proposal output screen 1210 mainly includes two regions. One region is design reference information 1211 for displaying reference information used to generate the design proposal 1006, and the other region is a design proposal display section 1212 for displaying the generated design proposal itself.

In the design reference information 1211, information acquired from the case database 1005 is organized and described. The information is classified for each level, and the information acquired from the system level database 1100 is displayed as system level reference information 1213, the information acquired from the apparatus level database 1101 is displayed as apparatus level reference information 1214, and the information acquired from the control level database 1102 is displayed as control level reference information 1215.

As a result, information referred to in the generation of the design proposal 1006 can be clearly confirmed for each level.

Further, ID information 1216 and change content information 1217 are included in the respective pieces of reference information, that is, the system level reference information 1213, the apparatus level reference information 1214, and the control level reference information 1215.

The ID information 1216 is identification information indicating which case in the case database 1005 has been referred to, and is associated with the case database ID 1112 to enable search for a case as a reference source.

In addition, the change content information 1217 indicates a specific content of the corresponding design change, and provides information for confirming main points of the referred past case.

The design proposal 1006 generated by the design generation unit 1004 is displayed in the design proposal display section 1212. The design proposal 1006 includes the design information after the modification, which is generated based on the design content 1010, and is displayed such that the modified portion can be clearly identified. In particular, design change source information 1218 is displayed so as to correspond to the design reference information 1211 for the modified portion, so that it is possible to track how the modification has been made based on information as a reference source.

By utilizing the ID information 1216, the past case referred to in the output design proposal 1006 can be searched in the case database 1005, and validity of a change content related to the design change source information 1218 can be examined. As a result, it is possible not only to make it easy for the designer to confirm reliability and compatibility of the design proposal 1006, but also to enable utilization as basic information when further improvement is performed as necessary.

As described above, the design proposal output screen 1210 serves to make a process of generating the design proposal 1006 transparent and comprehensively provides information for examining the validity and quality of the generated design proposal. By cooperation between the design reference information 1211 and the design proposal display section 1212, the designer can efficiently and accurately proceed with a confirmation process for the generated design proposal.

FIG. 9 is a diagram illustrating a flowchart of a design generation process 1220 according to the first embodiment. A series of processing procedures until the design proposal 1006 is generated will be described according to step numbers.

Step S101: The reception unit 1001 receives the design content 1010 and the design purpose 1011 via the input user interface 1200.

The design content 1010 is provided in a format, for example, character information such as a design document or a program or image information such as a design drawing, and the design purpose 1011 is information describing a purpose and a requirement of the design change.

Step S102: The design analysis unit 1002 analyzes the input design content 1010, and generates the level design information 1007 in which the design content 1010 is hierarchized into elements and information indicating a relation between corresponding components.

The level design information 1007 may be generated using the generative AI or the like, or the level design information 1007 may be generated on a rule basis. In the level design information 1007, the elements included in the design content 1010 are described in a form of being separated into a plurality of levels.

Step S103: The search unit 1003 searches the case database 1005 for an applicable past case based on the design purpose 1011 and the level design information 1007, and outputs the search result 1016.

Specifically, the search unit 1003 extracts the case database ID 1112, the related element 1114, and the change content 1115 whose modification purpose matches the design purpose from the change information corresponding to the pre-change design information including the elements included in the level design information 1007, and outputs the extracted case database ID 1112, related element 1114, and change content 1115 as the past case.

The search result 1016 may include a plurality of past cases, and an optimal case can be selected by assigning a design priority. As a method of assigning the priority, a method such as the degree of impact due to a change in the past case, a degree of relevance with the design content 1010, scoring by a machine learning model, or similarity analysis between the vectorized design purpose 1011 and the modification purpose 1113 can be considered. In addition, in a case where the number of search results is excessively large, it is also possible to adopt only the top several search results with high priority.

Step S104: In a case where there is no past case obtained by the search unit 1003, the processing proceeds to step S105, and in a case where one or more search results are included, the processing proceeds to step S106.

Step S105: The user selects whether or not to reset the design content 1010 and the design purpose 1011 and to re-execute the design generation process 1220. In a case where the design generation process 1220 is to be re-executed, the processing returns to step S101, and in a case where the design generation process 1220 is not to be re-executed, the processing is terminated.

Step S106: The design instruction information 1017 is generated based on the design content 1010, the design purpose 1011, and the search result 1016. In the design instruction information 1017, the change content 1115 of the past case included in the search result 1016 is described, and a specific content of the design change in the past case is clarified as a design instruction. As a result, a modification policy reflecting the design purpose 1011 is clarified, and a design proposal with high accuracy and high consistency can be generated. As a method of generating the design instruction information 1017, mapping of information to a template or automatic generation using a language model can be considered.

Step S107: The design generation unit 1004 inputs the design instruction information 1017 to the trained model 1018 and generates the design proposal 1006. The design proposal 1006 is obtained by modification based on the design content 1010, and is output in a form including common elements. The generated design proposal 1006 is provided in a format similar to the design content 1010, such as a design document, a program, or a design drawing.

Step S108: The generated design proposal 1006 is displayed in the design proposal display section 1212 of the design proposal output screen 1210. In the design proposal 1006, the modified portion is clearly indicated, so that the designer can easily confirm the modified portion.

Step S109: The user confirms the design proposal 1006 through the design proposal output screen 1210. The design proposal includes the design reference information 1211, and a corresponding past case in the case database 1005 can be referred to based on the ID information 1216. As a result, the validity of the change content incorporated in the design proposal 1006 can be examined.

Step S110: In a case where it is determined in step S109 that redesign of the design proposal 1006 is necessary, the processing returns to step S101, and the input information is corrected again to perform redesign. In a case where it is determined that redesign is unnecessary, the processing is terminated. The necessity of redesign may be determined by the user who has given the design instruction, or a determination system trained by machine learning may be used.

As described above, the design generation process 1220 provides a mechanism for efficiently executing a series of flows from input of the design content 1010 to output, evaluation, and correction of the design proposal 1006, and implements efficiency improvement and quality improvement of the entire design process.

### Second Embodiment

In a second embodiment, a configuration that enables processing of a large-scale design task by adding a function to the design support apparatus described in the first embodiment will be described.

The total amount of information based on a design content 1010 and a design purpose 1011 in the large-scale design task is enormous, and thus, there is a possibility that a trained model 1018 cannot appropriately determine a portion to be modified. As a result, a risk that erroneous information or inappropriate modification is reflected in a design proposal 1006 increases. In order to solve such a problem, it is necessary to organize and shape input information into an amount of information that can be appropriately processed by the trained model 1018, and to advance a design proposal generation process step by step.

In the present embodiment, a method in which the design proposal generation process in a design generation unit 1004 is separated into a plurality of processes and the processing proceeds in stages is adopted.

FIG. 10 is a diagram illustrating a part of a configuration of a design support apparatus 10 to which a partial design function 2000 in the second embodiment is added.

The partial design function 2000 can efficiently and accurately generate a design proposal even in the large-scale design task by separating the design generation unit 1004 into a partial design unit 2001 and a design integration unit 2002, which are two main processing units, and clarifying roles of the partial design unit 2001 and the design integration unit 2002.

The partial design unit 2001 does not process all pieces of information included in the design content 1010, but extracts and reshapes only a part matching a search result 1016, thereby reducing the amount of information input to the trained model 1018. Such a process is performed by a corresponding portion extraction unit 2003, and the corresponding portion extraction unit 2003 generates corresponding portion design information 2005. The corresponding portion design information 2005 is obtained by specifying and extracting a portion highly related to the search result 1016 in the design content 1010, and implements information selection and simplification.

Further, the partial design generation unit 2004 included in the partial design unit 2001 generates partial design instruction information 2006 based on the corresponding portion design information 2005 and the search result 1016. The partial design instruction information 2006 is input to the trained model 1018, and a partial design proposal 2007 is generated. As a method of generating the partial design instruction information 2006, a method of mapping the corresponding portion design information 2005 and information of the search result 1016 to a template, or a method of automatically generating the partial design instruction information 2006 by utilizing a language model such as a generative AI can be considered.

In this manner, by extracting the corresponding portion of the design content 1010 and generating the partial design proposal 2007, it is possible to reduce a processing load of the trained model 1018 and efficiently generate an accurate partial design proposal.

Next, the design integration unit 2002 executes processing of modifying and integrating the entire design content 1010 based on the partial design proposal 2007 generated by the partial design unit 2001. In such a process, design integration instruction information 2008 including information of the partial design proposal 2007, the design content 1010, and the design purpose 1011 is generated and input to the trained model 1018, thereby generating the final design proposal 1006. The design integration instruction information 2008 embodies an instruction for reflecting the partial design proposal 2007 in the overall design, and a method of mapping the partial design proposal 2007, the design content 1010, and the design purpose 1011 to a template or a method of automatically generating the design integration instruction information 2008 by using a language model can be considered.

The design integration instruction information 2008 can also include corresponding portion information of the corresponding portion design information 2005 in the design content 1010, thereby clearly indicating an integration portion. In addition, the design integration instruction information 2008 can also include a modification content of a partial design obtained by modifying the corresponding portion design information 2005 when generating the partial design proposal 2007, so that it is possible to perform accurate integration at the time of integration processing by clarifying the modification content.

The design integration unit 2002 has a function of not only simply replacing the corresponding portion of the design content 1010 with the partial design proposal 2007, but also grasping a portion requiring further modification and performing corresponding modification in a case where modification based on the partial design proposal 2007 affects another portion. With such a dynamic response, the partial design proposal 2007 is integrated while maintaining consistency with the entire design.

As described above, the partial design function 2000 is intended to efficiently process a huge amount of information and generate an accurate and consistent design proposal 1006 by separating a design task into a partial design generation process in the partial design unit 2001 and an integration process in the design integration unit 2002. With the function, processing accuracy in the large-scale design task is improved, and efficiency of the entire design process is improved while maximally utilizing performance of the trained model 1018.

FIG. 11 is a view illustrating an example of a design integration instruction information template 2100.

The design integration instruction information template 2100 is intended to efficiently and accurately execute design integration processing utilizing the generative AI, and includes components that are used to generate the design integration instruction information 2008 to be input to the generative AI and play an important role in the design proposal generation process.

The design integration instruction information template 2100 first includes a processing purpose 2101 for clarifying a purpose of the processing and a final output target 2102 indicating a final output target of the design integration processing. Such pieces of information are used to specifically indicate an overall policy in design integration to the generative AI.

Next, the template is provided with a region for receiving the input information necessary for the design integration processing. Specifically, the template includes a design content input section 2103 for inputting the design content 1010 and a partial design proposal input section 2104 for inputting the partial design proposal 2007. As a result, it is possible to provide the partial design proposal 2007 generated by the partial design unit 2001 and the original design content 1010 for the integration processing.

Furthermore, the template includes a processing procedure 2105 for instructing a specific procedure of the integration processing so that the generative AI can accurately generate the design proposal 1006. The processing procedure 2105 can include an instruction that takes into account necessity of further modification that occurs with modification of the corresponding portion, thereby supporting the generative AI to make appropriate modification while maintaining overall design integrity.

By utilizing such a template, it is possible to appropriately modify or improve only a target portion while effectively reducing the amount of information when integrating a partial design result into the final design. As a result, a risk of erroneous modification is reduced, and occurrence of redesign and rework can be suppressed. As a result, time reduction and cost reduction of the entire design task are achieved.

In addition, such a partial design process is effective particularly in a very large-scale design task. By adopting such a method, efficient and accurate design support can be performed even for a design target having enormous information that is difficult to process by a conventional method. The design integration instruction information template 2100 is an example that organizes information necessary for integrating the partial design proposal 2007 and the design content 1010 and provides a basis for the generative AI to appropriately operate, and plays an important role in processing of the large-scale design task.

As described above, the efficiency, accuracy, and flexibility of the design task are improved, and it is possible to reduce a burden on a designer and optimize the entire design process. That is, the cost for the design work is greatly reduced, and a lead time is shortened.

### Third Embodiment

In a third embodiment, an example in which a new function is added to the design support apparatus 10 of the first embodiment in order to appropriately incorporate a plurality of search results 1016 obtained in a design task into a design proposal 1006 will be described.

In a case where there are a plurality of search results 1016, an amount of input information included in design instruction information 1017 becomes enormous, and it becomes difficult for a trained model 1018 to output the design proposal 1006 simultaneously considering all the search results. In addition, since the plurality of search results may interfere with each other and cause inconsistency, it is difficult to generate an optimal design proposal by single processing. In order to solve such a problem, in the present embodiment, a method of adding an iterative processing function to a design generation unit 1004 and generating a design proposal in stages is adopted.

FIG. 12 is a diagram illustrating a configuration of a design support apparatus 3000 to which an iteration function is added.

The design support apparatus 3000 with the iteration function is obtained by adding a search result selection unit 3001, a termination determination unit 3004, and a temporary design proposal modification unit 3005 to the conventional design support apparatus 10. By using such new functions, a process of applying the search results 1016 in stages and generating the design proposal 1006 is implemented.

First, the search result selection unit 3001 selects the search result to be applied to modification of a design content 1010. Based on the selection, a search result 3002 to be applied is selected from among the plurality of search results 1016. As a selection method, a method of selecting one or a designated number of search results from among search results with high priority, or a method in which a user browses the search results 1016 and selects a search result from among the search results 1016 can be considered. For determination of the priority, it is possible to use the degree of impact due to a change in a past case, the degree of relevance with a design purpose 1011, scoring by a machine learning model, similarity analysis between the vectorized design purpose 1011 and a modification purpose 1113 in a case database 1005, determination using a language model, and the like.

Next, the design generation unit 1004 generates the design instruction information 1017 based on the search result 3002 to be applied, the design purpose 1011, and the design content 1010, and generates a temporary design proposal 3003 by using the trained model 1018. The temporary design proposal 3003 has a format equivalent to that of the design proposal 1006, and is generated as a proposal in which the search result 3002 to be applied is reflected in the design content 1010.

After the temporary design proposal 3003 is generated, the termination determination unit 3004 confirms whether or not there remains an unapplied search result 1016. Furthermore, it is simultaneously confirmed whether or not the number of times of iterative processing has not reached a prescribed number.

In a case where an unapplied search result remains and the number of iterations is less than the prescribed number, the termination determination unit 3004 does not execute termination processing and passes the temporary design proposal 3003 to the temporary design proposal modification unit 3005. The temporary design proposal modification unit 3005 unifies a form of the temporary design proposal 3003 with the design content 1010 and inputs the temporary design proposal 3003 to a design analysis unit 1002 again. By such a process, redesign using the new search result 3002 to be applied is performed.

On the other hand, in a case where the termination determination unit 3004 determines that there is no unapplied search result or the number of iterations has reached the prescribed number, the iterative processing is terminated, and the temporary design proposal 3003 is output as the final design proposal 1006.

In this way, a consistent design proposal is generated while stepwise and efficiently applying a plurality of search results.

As described above, in the design support apparatus 3000 with the iteration function, even in a case where the plurality of search results 1016 are obtained, each result can be appropriately incorporated into the design proposal. By executing the iterative processing, it is possible to avoid information inconsistency and interference and support the trained model 1018 to generate an accurate and consistent design proposal 1006. By such a mechanism, efficiency improvement and quality improvement of the entire design process are implemented, and an environment in which a designer can smoothly proceed a large-scale and complex design task is provided.

FIG. 13 is a diagram illustrating a flowchart illustrating an iterative design generation process 3010 of the design support apparatus 3000 with the iteration function. Steps S301, S302, and S303 are added to a design generation process 1220 illustrated in FIG. 9.

The process includes the iterative processing for appropriately reflecting the plurality of search results 1016 in the design proposal 1006, and is intended to improve accuracy in design proposal generation.

Step S301: It is determined whether or not a search result 1016 that is unapplied to the generation of the temporary design proposal 3003 is present. The determination is performed as a partial function of the termination determination unit 3004. Specifically, the temporary design proposal 3003 generated in step S107 is received, and it is confirmed whether the search result 1016 that has not been reflected in the processing so far remains. In a case where the unapplied search result is absent, the iterative processing is terminated, the temporary design proposal 3003 is determined as the final design proposal 1006, and the processing proceeds to step S108. On the other hand, in a case where the unapplied search result is present, the processing proceeds to the next step S302.

Step S302: It is determined whether or not the number of times of the iterative processing has reached the upper limit number of iterations set in the system. The function is also executed as a part of the termination determination unit 3004. The upper limit number of iterations may be set by the reception unit 1001 or may be designated through a separately provided setting screen or an environment variable. In a case where the number of iterations has reached the upper limit, the iteration processing is terminated, the temporary design proposal 3003 is determined as the design proposal 1006, and the processing proceeds to step S108. In a case where the number of iterations has not reached the upper limit, the processing proceeds to the next step S303.

Step S303: Processing of converting the temporary design proposal 3003 into a form similar to the design content 1010 is executed. The processing is executed through the temporary design proposal modification unit 3005. By shaping the temporary design proposal 3003 into the same format as the design content 1010, the temporary design proposal 3003 can be input into the design analysis unit 1002 again. As a processing method in the temporary design proposal modification unit 3005, a method of performing automatic conversion using the generative AI or a method of shaping information based on the template of the design content can be considered. After the process is completed, the processing returns to step S102 again, and the design generation process is repeated.

By adopting the process, a burden of rework on humans in a final checking stage for the design proposal 1006 is reduced. As a result, significant reductions in development cost and development period can be expected. As described above, the iterative design generation process 3010 provides an optimal method for efficiently and accurately reflecting a plurality of past cases in the design proposal, and further improves practicality of the design support apparatus.

### Fourth Embodiment

In a fourth embodiment, in order to cope with a system design having a complex connection between elements and a complex flow of information, a configuration in which an information organization function focusing on element information and connection information among design information is added to the design support apparatus 10 of the first embodiment will be described.

In particular, in design of a production system, an economic model, or the like in which a connection between elements is important, not only simple element information but also information regarding how the elements are connected is important information in determining applicability of a past case. Therefore, in the present embodiment, level design information 1007 and an information format in a case database 1005 are extended and changed to a form including the element information and information regarding the connection between the elements.

FIGS. 14A, 14B, and 14C are diagrams illustrating examples of system level information 4000 including connection information. The system level information 4000 including the connection information represents a specific example of information in a database in a specific level of the case database 1005 and information in a specific level of the level design information 1007. Such an example is based on a chemical material production system for reacting and separating chemical materials, and describes elements in the system and a connection between the elements to clearly indicate an overall structure of the system.

The system level information 4000 including the connection information includes a system ID 4001 and component information 4010 and relationship information 4020, which are associated with each other by the system ID 4001.

FIG. 14A is a diagram illustrating an example of a system operation flowchart 4009 of the system level information 4000 including the connection information.

In the example of FIG. 14A, the operation flowchart 4009 of the chemical material production system is illustrated, which starts from start 4002, and a raw material is introduced into a reaction tank 4003, and heating is performed by a heating apparatus 4004. Thereafter, a reactant whose reaction has been completed is transferred to a separation tank 4006, the material is separated by being depressurized by a pump 4007, and a product finally reaches end 4008 to complete the reaction.

Such a process is expressed by two types of information, the component information 4010 and the relationship information 4020. For example, a relationship 4005 between the reaction tank 4003 and the heating apparatus 4004 is stored in the relationship information 4020.

FIG. 14B is a diagram illustrating an example of the component information 4010 of the system level information 4000 including the connection information.

The component information 4010 holds information regarding all apparatuses included in the corresponding system, and includes an apparatus name 4011, an attribute 4012, an apparatus ID 4013, and a description 4014 of element. As a result, it is possible to clarify a specific characteristic and a role of each element included in the system.

The component information 4010 is managed by the system ID 4001 and an element information ID 4015.

FIG. 14C is a diagram illustrating an example of the relationship information 4020 of the system level information 4000 including the connection information.

The relationship information 4020 holds information regarding a connection between the apparatuses in the corresponding system, and includes a first apparatus ID 4021, a second apparatus ID 4022, a relationship 4023, and a description 4024 of connection.

The first apparatus ID 4021 and the second apparatus ID 4022 are associated with the apparatus ID 4013 in the component information 4010, and express the connection between the respective apparatuses. For example, in the relationship 4005 between the reaction tank 4003 and the heating apparatus 4004, a process of heating the reactants is described as “relationship”, and a specific content thereof is described as “description of connection”, so that an operation between the apparatuses and the information flow can be recorded in detail.

In this way, by holding two types of information, the component information 4010 and the relationship information 4020, it is possible to generate apparatus information in consideration of not only the simple element information but also the connection and the relationship between the elements. As a result, accuracy in analysis and search is improved, and applicability of the past case can be more appropriately determined.

Furthermore, by reflecting the description 4014 of element of the component information 4010 and the description 4024 of connection of the relationship information 4020 in the search result, design instruction information 1017 can be described more clearly. As a result, when a trained model 1018 generates a design proposal 1006 based on the design instruction information 1017, it is possible to perform modification in consideration of the relationship between the elements, so that accuracy in design proposal generation is further improved.

As described above, by introducing information organization in which the element information and the connection information are combined, it is possible to generate an appropriate and clear design proposal even in system design in which a connection between elements is complex. Such a method greatly improves usefulness of the design support apparatus particularly in designing a production system having a complex structure or an economic model in which a relationship between elements is important.

FIG. 15 is a diagram illustrating an example of a connection-information-containing system level database 4100.

The connection-information-containing system level database 4100 is the case database 1005 configured based on the system level information 4000 including the connection information. The connection-information-containing system level database 4100 comprehensively manages detailed information regarding a design change in the past case, and provides a basis for further improving design support accuracy in complex system design.

The connection-information-containing system level database 4100 includes information such as a system ID 4101, a system name 4102, a pre-change component information ID 4103, a pre-change relationship information ID 4104, a post-change component information ID 4105, a post-change relationship information ID 4106, a change content 4107, and a change purpose 4108.

The system ID 4101 is associated with ID information 1216 displayed on a design proposal output screen 1210 so that detailed information of the past case reflected in the design proposal 1006 can be easily referred to. As a result, the past case used for generating the design proposal 1006 can be tracked, and convenience when the designer confirms the content is improved.

The pre-change component information ID 4103 and the pre-change relationship information ID 4104 each represent design information before the change of the system in the past case, and the pre-change component information ID 4103 and the pre-change relationship information ID 4104 correspond to the component information 4010 and the relationship information 4020 illustrated in FIG. 14.

Similarly, the post-change component information ID 4105 and the post-change relationship information ID 4106 represent the design information after the change of the system in the past case, and are also described in formats of the component information 4010 and the relationship information 4020. Such pieces of information are associated with the element information ID 4015 and the relationship information ID 4025, respectively, so that the pieces of design information before and after the change are managed with consistency.

The change content 4107 describes a difference between the design information before the change and the design information after the change, the design information before the change being represented by the pre-change component information ID 4103 and the pre-change relationship information ID 4104, the design information after the change being represented by the post-change component information ID 4105 and the post-change relationship information ID 4106. As a result, it becomes possible to clearly grasp what kind of design change has been made in the past case.

Since the change content 4107 is present, it is possible to specifically describe a design change case based on the past case in a search result 1016 and the design instruction information 1017, so that the trained model 1018 can accurately perform the design change based on the information. As a result, accuracy of the design proposal 1006 is improved, and re-correction and rework are reduced, so that reduction in design cost and design time can be expected.

The change purpose 4108 is information describing a purpose of the design change in the past case, and is an important element when searching based on a design purpose 1011. The change purpose 4108 may be in a sentence format or a word format, and as a search method, a word search or a method of extracting an embedding vector from a word or a sentence using a machine learning model or the like and calculating a vector similarity can be considered. In this way, it is possible to efficiently search for a past case having the change purpose 4108 that is most relevant to the design purpose 1011.

As described above, the connection-information-containing system level database 4100 provides a powerful tool for managing a design change process of the past case in detail. Using the database contributes not only to improvement of quality of the design proposal by accurate utilization of the past case in the generation of the design proposal 1006, but also to improvement of efficiency of the entire design process. In addition, by integrally handling both the element information and the connection information, it is possible to effectively utilize the past case even in particularly complex system design. Such a mechanism further improves practicality and reliability of the design support apparatus, and can bring a great advantage to the designer.

FIG. 16 is a diagram illustrating an outline of a process of extracting difference information by using elements and a connection of design change information.

In FIG. 16, a method of clarifying a difference between the pre-change system information 4121 is changed to the post-change system information 4122 in a case where a change from the pre-change system information 4121 to the post-change system information 4122 is made is described. In the example, the difference is that a new connection I connecting elements A and C is made. By extracting the difference information, it is possible to acquire pre-change related system information 4123 including only a related portion before the change and system change information 4124 describing the change content.

By storing the pre-change related system information 4123 and the system change information 4124 in the case database 1005, in a case where the pre-change related system information 4123 is included in the level design information 1007, it can be determined that the pre-change related system information 4123 corresponds to the search result 1016. On the other hand, in a case where the pre-change related system information 4123 is not included in the level design information 1007, it is determined that the pre-change related system information 4123 is not included in the search result 1016. In this way, by using the difference information in consideration of the elements and the connection, it is possible to more accurately determine the past case applicable to the design content 1010.

In an approach illustrated in FIG. 16, several methods are conceivable as a search method for a system having information regarding elements and a connection. One of the methods is a method of determining whether or not all change-related elements in the design information before the change are included in the level design information 1007. Another one of the methods is partial isomorphism determination for determining whether or not shapes of the elements and the connection partially match. By using the partial isomorphism determination, it is possible to evaluate not only whether or not the elements simply match but also whether or not the entire structure including the connection matches.

FIG. 17 is a diagram illustrating a specific example of the partial isomorphism determination.

Here, a process of searching for a structure in which a determination target system 4201 is partially included is described. For example, in a system example 4202 that includes a determination target, an element A, an element B, and an element D are included, and the elements A, B, and D are connected like D-A-B. However, in a system example 4203 that does not include the determination target, it is determined that the determination target system 4201 is not included since there is no connection between the element D and the element A even if the element A, the element B, and the element D are included (a connection 4204 is absent). As described above, the isomorphic determination in consideration of not simple matching of the elements but the connection plays an important role.

As a method of the isomorphic determination, a VF2 algorithm or the like, which is one of graph algorithms, is effective. Further, not only the partial isomorphism determination but also a method using graph similarity such as spectral graph analysis can be considered. As a result, even in a system having a complex connection between elements, it is possible to acquire an appropriate past case as the search result 1016.

The design support apparatus considering the information regarding the elements and the connection as in the present embodiment can support a system design having a complex and large-scale relationship. For example, in the economic model, companies or administrations are expressed as the elements, and a transaction or a relationship between the companies or administrations can be expressed as the connection. In this case, in a lower level, it is possible to express factories owned by the respective companies as the elements and express distribution between the factories as the connection. In a deeper level, production systems, facilities, and the like can be treated as the elements, and a connection relationship therebetween can be described. In a system design having such a level structure, information organization based on the elements and the connection is extremely useful.

For example, in the case of executing automatic design intended for improving a cash flow of a company, a cash flow improvement plan, a distribution improvement plan, and the like in a production system of a lower level are automatically applied, and a design proposal obtained by integrating the results can be presented. As described above, partial improvement is also reflected in the system design of a higher level, so that the design proposal of the entire economic model can be efficiently and accurately generated.

As described above, the design support apparatus considering the information regarding the elements and the connection improves accuracy and efficiency of design proposal generation in complex system design, and is expected to be applied in various fields. In particular, in a multilayered system design such as an economic model or a large-scale production system, usefulness of the design support apparatus is remarkable, and the design support apparatus contributes to reduction in design cost and time and improvement in design quality.

This invention is not limited to the above-described embodiments but includes various modifications. The above-described embodiments are explained in details for better understanding of this invention and are not limited to those including all the configurations described above. A part of the configuration of one embodiment may be replaced with that of another embodiment; the configuration of one embodiment may be incorporated to the configuration of another embodiment. A part of the configuration of each embodiment may be added, deleted, or replaced by that of a different configuration.

The above-described configurations, functions, processing modules, and processing means, for all or a part of them, may be implemented by hardware: for example, by designing an integrated circuit. The above-described configurations and functions may be implemented by software, which means that a processor interprets and executes programs providing the functions.

The information of programs, tables, and files to implement the functions may be stored in a storage device such as a memory, a hard disk drive, or an SSD (a Solid State Drive), or a storage medium such as an IC card, or an SD card.

The drawings shows control lines and information lines as considered necessary for explanation but do not show all control lines or information lines in the products. It can be considered that almost of all components are actually interconnected.

1. A computer that supports design for design information including definitions of elements included in an object that is a design target, the computer comprising:
a processor;
a storage device connected to the processor; and
a network interface connected to the processor, wherein
the storage device is configured to store first hierarchized design information obtained by classifying the elements included in past design information of the object based on a hierarchization rule for the elements and grouping the elements by the same level, and case data in which the element included in the past design information is associated with a change purpose and a change content of the element, and
the processor is configured to:
receive target design information and a design purpose;
generate second hierarchized design information by hierarchizing the target design information;
search for the first hierarchized design information including the same element as the element included in the second hierarchized design information with reference to the first hierarchized design information and the second hierarchized design information in the same level;
search for the case data in which a combination of the element and the design purpose included in the second hierarchized design information matches a combination of the element and the change purpose of the element, from pieces of the case data associated with the searched first hierarchized design information; and
generate a design proposal in which the target design information is modified according to the design purpose by inputting a prompt including the searched first hierarchized design information and the searched case data to a language model.

2. The computer according to claim 1, wherein the processor is configured to input, to the language model, a first prompt that includes the searched first hierarchized design information, the searched case data, the target design information, and the design purpose and instructs generation of the design proposal.

3. The computer according to claim 2, wherein the processor is configured to:
generate partial design information by extracting a portion corresponding to the searched case data from the target design information;
generate a partial design proposal, in which the partial design information is modified, by inputting, to the language model, a second prompt that includes the searched first hierarchized design information, the searched case data, the partial design information, and the design purpose, and instructs generation of the partial design proposal; and
generate the design proposal by inputting, to the language model, a third prompt that includes the partial design proposal, the target design information, and the design purpose and instructs generation of the design proposal.

4. The computer according to claim 3, wherein
the second prompt includes an instruction to output a modification content of the partial design information together, and
the third prompt includes the modification content of the partial design information and includes an instruction to select the partial design proposal to be applied by using the modification content of the partial design information, and generate the design proposal by using the selected partial design proposal.

5. The computer according to claim 1, wherein the processor is configured to:
execute processing of generating a temporary design proposal, in which the target design information is modified according to the design purpose, by selecting a predetermined number of pieces of the case data in a case where a plurality of pieces of the case data are searched, and inputting, to the language model, a fourth prompt that includes the selected case data, the first hierarchized design information corresponding to the case data, the target design information, and the design purpose and instructs generation of the temporary design proposal;
execute, in a case where it is necessary to execute the processing again, the processing after setting the temporary design proposal as the target design information; and
output, in a case where it is not necessary to execute the processing again, the temporary design proposal as the design proposal.

6. The computer according to claim 1, wherein
the design information includes a definition of a connection between the elements,
the storage device is configured to store third hierarchized design information in which the elements included in modified design information obtained by modifying the past design information of the object are classified and grouped by the same level, and difference information, which is a difference between a definition of a connection between the elements included in the first hierarchized design information and a definition of a connection between the elements included in the third hierarchized design information, and
the processor is configured to search for the first hierarchized design information corresponding to the difference information partially or completely matching a definition of a connection between the elements included in the second hierarchized design information with reference to the definition of the connection between the elements included in the first hierarchized design information of the same level and the difference information corresponding to the second hierarchized design information.

7. The computer according to claim 6, wherein the processor is configured to determine whether or not the difference information partially or completely matches the definition of the connection between the elements included in the second hierarchized design information by using an algorithm of partial graph isomorphism determination.

8. The computer according to claim 1, wherein the processor is configured to output an interface for inputting the target design information and the design purpose, and an interface for presenting the design proposal.

9. A design support method for design information including definitions of elements included in an object that is a design target, the design support method being executed by a computer, the computer including a processor, a storage device connected to the processor, and a network interface connected to the processor, the storage device storing first hierarchized design information obtained by classifying the elements included in past design information of the object based on a hierarchization rule for the elements and grouping the elements by the same level, and case data in which the element included in the past design information is associated with a change purpose and a change content of the element, the design support method comprising:
receiving, by the processor, target design information and a design purpose;
generating, by the processor, second hierarchized design information by hierarchizing the target design information;
searching, by the processor, for the first hierarchized design information including the same element as the element included in the second hierarchized design information with reference to the first hierarchized design information and the second hierarchized design information in the same level;
searching, by the processor, for the case data in which a combination of the element and the design purpose included in the second hierarchized design information matches a combination of the element and the change purpose of the element, from pieces of the case data associated with the searched first hierarchized design information; and
generating, by the processor, a design proposal in which the target design information is modified according to the design purpose by inputting a prompt including the searched first hierarchized design information and the searched case data to a language model.
